(19) United States
(12) Patent Application Publication
(10) Pub. No.: US 2013/0256697 A1
(43) Pub. Date: Oct. 3, 2013

(54) GROUP-III-NITRIDE BASED LAYER STRUCTURE AND SEMICONDUCTOR DEVICE

(71) Applicants: Armin Dadgar, Berlin (DE); Alois Krost, Berlin (DE)

(72) Inventors: Armin Dadgar, Berlin (DE); Alois Krost, Berlin (DE)

(73) Assignee: AZZURRO SEMICONDUCTORS AG, Magdeburg (DE)

(21) Appl. No.: 13/993,105

(22) PCT Filed: Dec. 23, 2011
(86) PCT No.: PCT/EP2011/074042

§ 371 Date: Jun. 11, 2013

(30) Foreign Application Priority Data
Dec. 26, 2010 (DE) 10 2010 056 409.5

(51) Int. Cl. H01L 29/20

(52) U.S. Cl. CPC H01L 29/2003
USPC 257/76

(57) ABSTRACT

A group-III-nitride based layer sequence fabricated by means of an epitaxial process on a silicon substrate, the layer sequence comprising at least one doped first group-III-nitride layer (105) having a dopant concentration larger than 1×10¹⁸ cm⁻³, a second group-III-nitride layer (106) having a thickness of at least 50 nm and an n-type or p-type dopant concentration of less than 5×10¹⁸ cm⁻³, and an active region made of a group-III-nitride semiconductor material, wherein the first group-III-nitride layer comprises at least one n-type dopant selected from the group of elements formed by germanium, tin, lead, oxygen, sulphur, selenium and tellurium or a at least one p-type dopant, and wherein the active region has a volume density of either screw-type or edge type dislocations below 5×10⁹ mm⁻³.

The present invention relates to a group-III-nitride based layer structure and a semiconductor device comprising this layer structure.

Group-III-nitride based layer structures and semiconductor devices comprising such layer structures, in particular transistors and diodes, are excellently suited high-voltage devices due because they allow achieving a high breakdown electric field. However, a low-cost manufacture of, for example, Schottky or p-i-n-diodes has not been possible. This is due to a large density of dislocations, which is responsible for an early electric breakdown of the devices under vertical current in a direction of the c-axis. For this reason, these devices are often made on expensive GaN-substrates.

Efforts are being made to manufacture these devices on silicon substrates. This would reduce the manufacturing cost due to the availability of large-diameter wafers, enable a simple manufacture of contacts and, finally, an integration with silicon electronics on the same chip.

Many semiconductor devices of the kind mentioned above have at least one highly doped n-type group-III-nitride layer for connecting and distributing current. A doping with silicon, which is common today, generates a strong tensile stress in group-III-nitride layer structures during growth or at least reduces an existing compressive stress. On silicon substrates, however, a compressive stress is required during layer growth in order to obtain a crack-free layer structure after cooling from the growth temperature to room temperature.

An object underlying the present invention is to optimize a layer structure of group-III-nitrde layers on silicon substrates. A further object of the present invention is to improve the performance of diode structures based on a group-III-nitride layer structure, such as a Schottky diode or a p-i-n diode, in particular in the form of a light emitting diode.

In accordance with the present invention a group-III-nitride based layer sequence fabricated by means of an epitaxial process on a silicon substrate is provided, the layer sequence comprising:
at least one n-type doped first group-III-nitride layer having an n-type dopant concentration larger than 1×10¹⁸ cm⁻³;
a second group-III-nitride layer having a thickness of at least 50 nm and an n-type or p-type dopant concentration of less than 5×10¹⁸ cm⁻³; and
an active region made of a group-III-nitride semiconductor material;
wherein the first group-III-nitride layer either comprises at least one n-type dopant selected from the group of elements formed by germanium, tin, lead, oxygen, sulphur, selenium and tellurium or at least one p-type dopant; and wherein
the active region has a volume density of either screw-type or edge type dislocations below 5×10⁹ cm⁻³.

In the following, embodiments of the layer structure will be described.

In one embodiment the second group-III-nitride layer has an n-type or p-type dopant concentration of less than 5×10¹⁷ cm⁻³.

In embodiments of the layer sequence, which are suitable in particular for use in the manufacture of vertical diodes, the second group-III-nitride layer has a thickness of at least 500 nm, preferably even between 2 and 10 μm.

The active region preferably has a volume density of screw-type dislocations below 5×10⁸ cm⁻³. Even more preferably, this density value is below 1×10⁸ cm⁻³.

The dopant concentration of first group-III-nitride layer is in one embodiment, which is suitable for fabricating Schottky diode, or a p-i-n diode (such as a LED), an n-type dopant concentration. In particular, the use of Germanium as an n-type dopant in the second group-III-nitride layer allows achieving high quality devices. Germanium as an n-type dopant allows fabricating n-type group-III-nitride layer sequences on a silicon substrate with a cleary lower tensile strain during growth than the conventional silicon doping. This in turn allows growing thicker group-III-nitride layers with higher quality. This results in an active region of the device as a top part of this layer sequence and having particularly low dislocation density, in particular screw-type dislocation density. First experiments show that, due to their similarity with Germanium as an n-type dopant in group-III-nitrides, n-type doping with tin, lead, oxygen, sulphur, selenium and tellurium is to be expected to have at least similar advantageous effects.

In an alternative embodiment, which is suitable for fabricating an alternative p-i-n diode structure, a p-type dopant concentration may be used for the first group-III-nitride layer. The first group-III-nitride layer thus forms the p-layer of this alternative p-i-n diode structure.

A masking layer may be used to optimize the layer quality and support the stress management. To this end, the layer structure preferably further comprises a layer of silicon nitride, silicon oxide, boron nitride or aluminum oxide or a mixture of at least two of these materials. The layer is in different embodiments an in-situ deposited layer or an ex-situ deposited layer.

The silicon substrate may be a bulk silicon wafer. However, in another embodiment it has a silicon-on-insulator structure.

The volume density of edge-type dislocations in the active region is preferably even below 2×10⁹ cm⁻³.

In another embodiment, the volume density of edge-type dislocations in the active region is below 5×10⁸ cm⁻³.

The layer sequence of the present invention and its embodiments can be used for different applications of semiconductor device. The semiconductor device is for instance configured either as a Schottky diode, a p-i-n diode or as a light emitting diode. Preferably, the semiconductor device is configured to allow a vertical flow of current through its active region.

In the following, further embodiments of the present invention will be described with reference to the enclosed Figures.

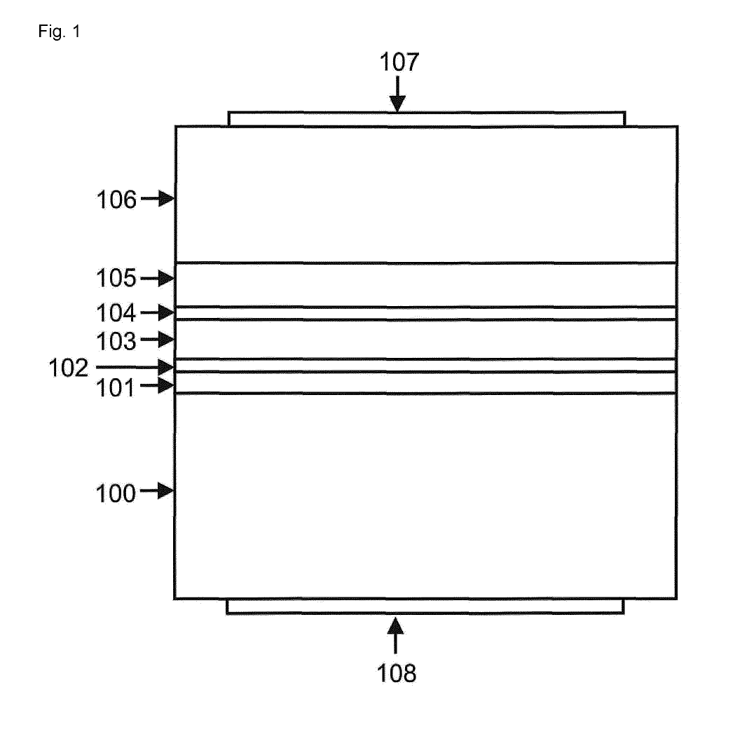

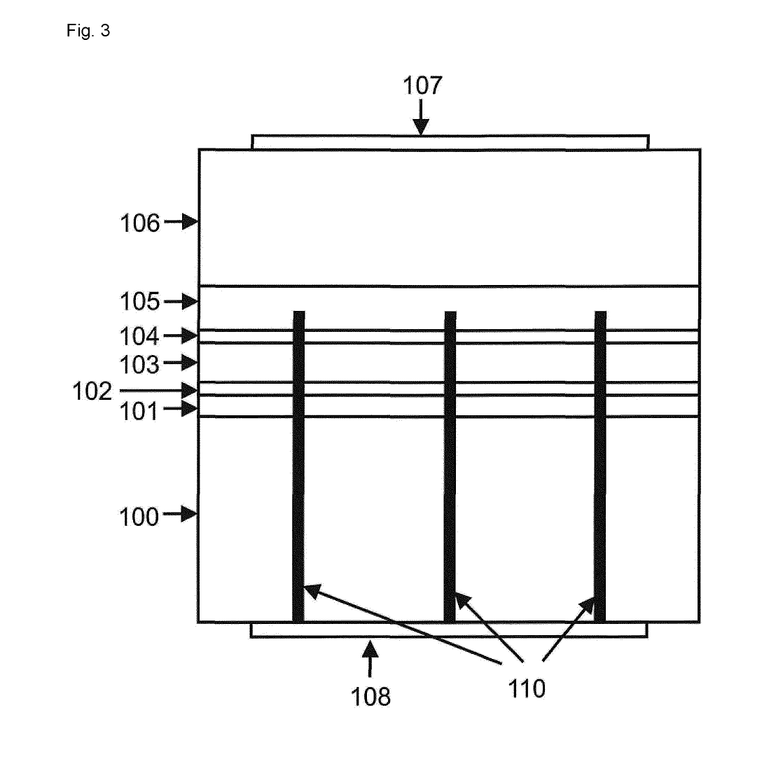

FIGS. 1, 3, 4 and 5 show embodiments of layer structures suitable for in cooperation into semiconductors devices such as Schottky diodes.

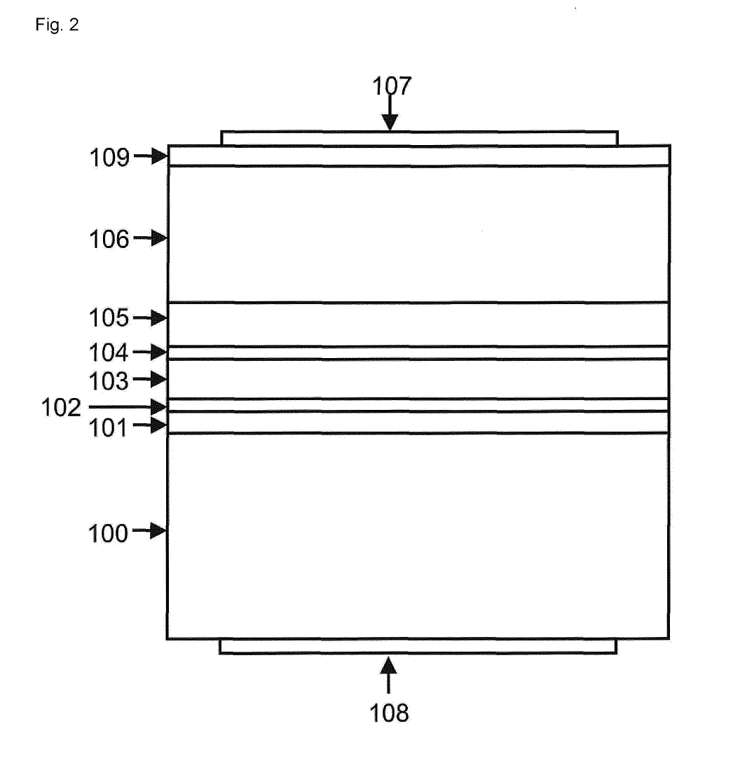

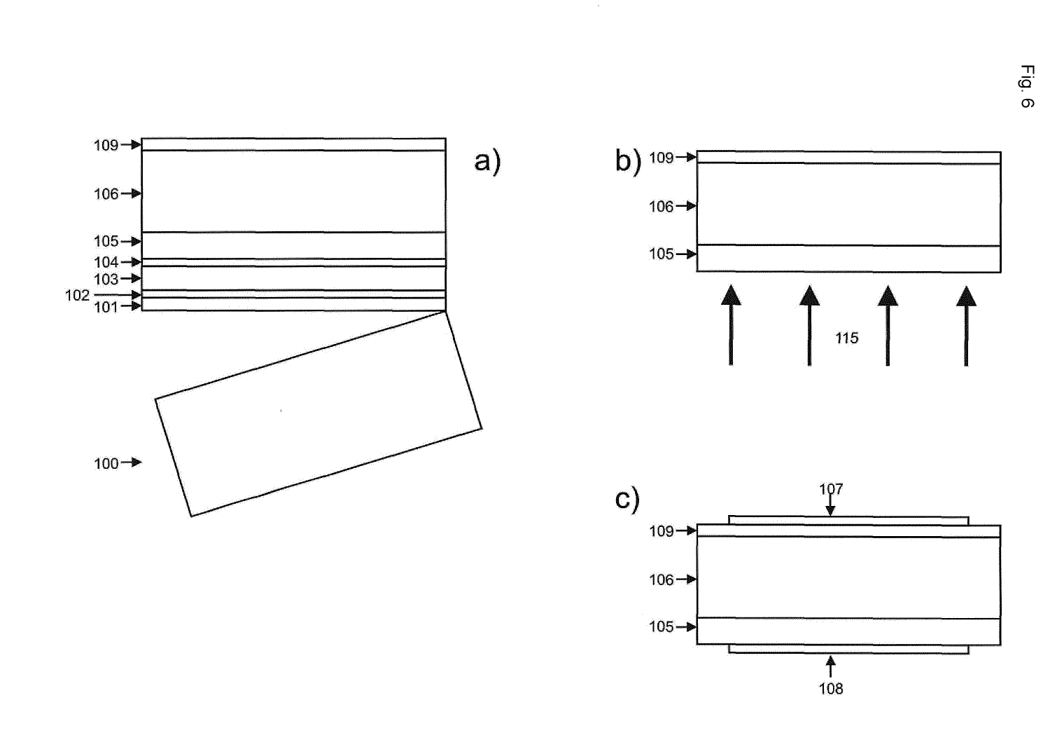

FIGS. 2 and 6 show different embodiments of a p-i-n diode.

It is noted that the embodiments described in the following are only exemplary in nature. A combination of different features of these embodiments is generally possible. In particular, intermediate layers and undoped layers or layers, which may either be doped or undoped, may be combined which each other repeatedly. This way the total thickness of a layer structure may be increased, the material quality may be enhanced and the stress management, that is, the stress present during growth, maybe optimized.

With reference to FIG. 1, a layer structure for use a semiconductor device is shown in a schematic cross sectional view. The layer structure is fabricated on a substrate 100. The substrate 100 is for instance be a silicon substrate. As variants, a silicon-on-insulator (SOI) or a substrate fabricated using a SIMOX-technology (SIMOX=separation by implanted oxygen) may be used. The latter two substrate examples can be advantageous in regard to isolation or voltage breakdown in inverse direction.

It is noted that substrates made of another material or a combination of other materials may be used, provided the material or combination has a coefficient of thermal expansion that is similar to that of silicon, that is, in the range of 2 to 3×10⁻⁶ K⁻¹. This range of the coefficient of thermal expansion is clearly below those values, which have been measured for group-III-nitride materials to be used in the present context. This range therefore results in a tensile stress of the fabricated layer structure after the manufacturing process.

On the substrate 100, a layer 101 is grown. The layer 101 in FIG. 1 is a schematic representation of a seed and buffer layer structure. The layer 101 may be made from AlN or AlGaN. In an alternative embodiment it is made from a layer stack of AlGaN layers having different gallium contents between 0 and 1.

The seed and buffer layer 101 is followed by a masking layer 102. The masking layer 102 may fore instance be made of SiN or another material that inhibits the layer growth. An example of such alternative material is a group-III-nitride comprising several percent of boron (B). The masking layer may be deposited in situ. In this case, it has a nominal thickness in the range of a few monolayers, preferably between 0.5 and 1.0 nanometer. An in-situ masking layer helps achieving a low screw dislocation density, which is required for obtaining a high breakdown voltage with a low layer thickness.

The masking layer may in an alternative embodiment be deposited ex-situ. In this embodiment, the thickness is in the range of 10 to 100 nanometer.

It should be noted that the masking layer 102 is optional. It may be mitted.

The masking layer 102, or, if it is omitted, the seed and buffer layer 101 is followed by a further buffer layer 103. The further buffer layer 103 may be made of GaN. Typically, the buffer layer initially grows in a three-dimensional growth mode. Only after coalescence of the initial growth islands, the layer becomes smooth. The further buffer layer 103 may be doped. For n-doping, the dopant may be selected from the group of elements comprising germanium (Ge), tin (Sn), lead (Pb), oxygen (O), sulphur (S), selenium (Se) a tellurium (Te). These dopants allow achieving an undisturbed three-dimensional growth despite the in-situ doping process.

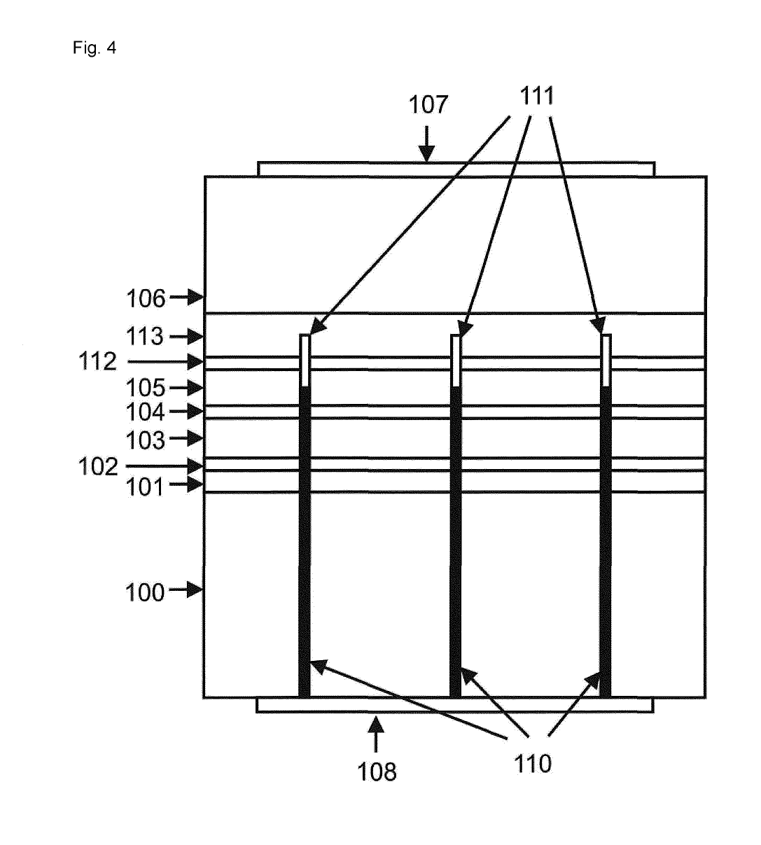

A doping of the further buffer layer 103 is particularly advantageous in case of a vertical contact structure, as shown in FIG. 1. In this type of embodiment, it is recommended to subject all layers up to a layer shown under reference label 105 or, if present reference label 113 (FIG. 4), respectively, to an n-doping using a dopant from the mentioned group of dopant elements.

It is noted in this context that the masking layer 102 of course cannot be doped. If a continuous doping of all layers is desired, the masking 102 may be omitted or the buffer layer 103 may be grown in a two-dimensional growth mode. However, this is less advantageous for the manufacturing process and not preferred.

As a further alternative to using the masking layer 102, a three-dimensional growth mode of the further buffer layer 103 may be forced by suitable growth parameters, such as a low ratio of group-V to group-III flow. However, even though this reduces the density of dislocations, the effect is not equally strong as in case of using the masking layer. Furthermore, there is less control of the growth mode when using this alternative. Thus, omitting the masking layer 102 may lead to an increased density of dislocations and thus to poorer breakdown characteristics.

Note that the masking layer may be deposited in-situ at a later stage during the manufacturing process of the layer structure, that is, with a larger distance from the substrate. The thickness of such masking layer deposited later is preferably selected to have little influence on the compressive stress bias. An optimization of the thickness may be performed with respect to avoiding cracks, avoiding a bow of the layer structure and achieving a desired material quality, in particular in terms of dislocation density.

An intermediate layer or layer structure 104 may be grown on the further buffer layer 103. This layer 104 is provided for modifying and managing the stress in the layer structure as a whole. The intermediate layer 104 is particularly useful on silicon substrates. It serves for providing a compressive stress during growth. To this end, is preferably inserted into the layer structure before deposition of the doped layer 105 in the embodiment of FIG. 1. The intermediate layer 104 is for instance made of AlN grown at low temperatures. Such low temperatures are typically in the range of 500 to 800° C. However, any temperature below 1.000° C. may be considered a low temperature in a chemical vapour deposition process of group-III-nitride materials.

The intermediate layer 104 may be inserted repeatedly into the layer structure, that is, at different distances from the substrate. This is shown for instance in the embodiment of FIG. 4, where an additional intermediate layer 112 is provided as a stress management measure. Here, it is preferred to deposit the additional intermediate layer 112 before fabricating an additional highly doped layer 113 that forms a repetition of the layer 105, which will be described next.

The highly doped layer 105 is herein also referred to as the first group-III-nitride layer. This layer preferably has a carrier concentration, for instance an electron concentration above 5×10¹⁸ cm⁻³, ideally around 1×10¹⁹ cm⁻³. For under these conditions, contact resistance is neglectable, in particular for the case of using large-area contacts. If a contact extending over the whole layer surface is used, the dopant concentration can be somewhat lower, but should be higher than 1×10¹⁸ cm⁻³. In the preferred case of n-type doping, Germanium is preferably used as a dopant.

Layer 106 also comprises the active region, which may be a light-emitting region in a LED, or more generally, an intrinsic region in a p-i-n region.

In an ideal case, the carrier concentration is identical to the dopant concentration. However, in practice the carrier concentration correlates with the dopant concentration over a large range of values, but due to compensation effects tends to be somewhat lower. The values of the dopant concentration given herein shall be understood as also representing an achieved carrier concentration, i.e., the concentration of electrons or holes that is not compensated by complementary defects. In practice, the dopant concentration may be selected somewhat higher to achieve a desired carrier concentration.

For achieving a good current guidance through the layer structure, a doping of the full lower part of the layer structure is useful. In the example of FIGS. 1 to 3 and 5 this lower part is the layer sequence of layers 101 through 105. In the embodiment of Fig. the lower part extends to layer 113.

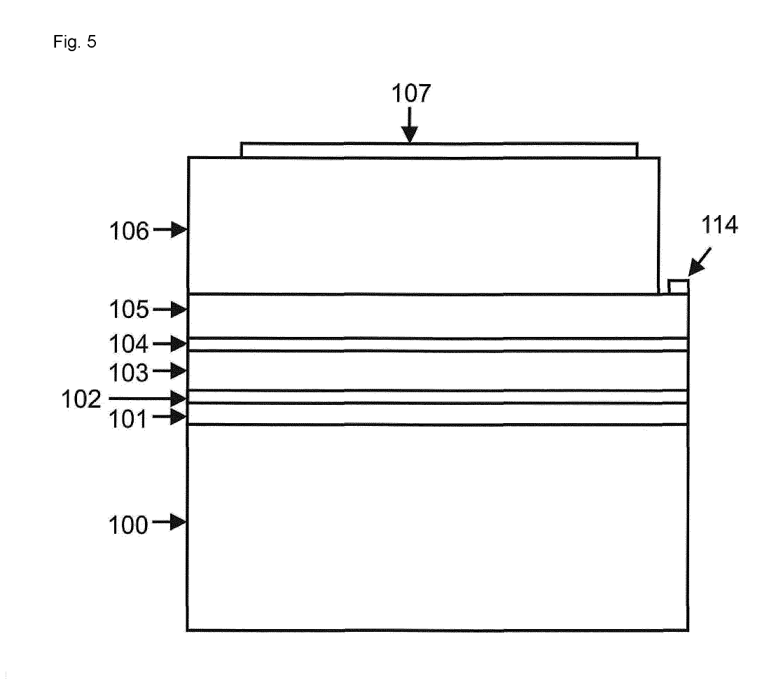

For contacting, different options are represented by the embodiments shown in the Figures. FIG. 5 shows a front contact 114 that is arranged on an etched portion of the layer 105. To this end, a region (not shown) adjacent to the front contact 114 is fully etched down to the substrate 100 and by suitable metallization forms a contact bridge to the substrate. This way, the device can be contacted vertically via the front and back side of the substrate or the layers, preferably by means of the corresponding contacts 108 and 107.

For a low-ohmic back side contact to the group-III-nitride layer through the contact 108, vias 110 can be used, which extend through the substrate and through a part of the layer sequence grown on the substrate. The vias can be fabricated by etching and metallization. The vias should end in the n-type layer 105 or 113. Depending on the number of intermediate layers, the vias 110 and 111 should be fabricated to end in the first highly n-doped layer 105 or, in the case of further doping in the layers that follow, in the uppermost highly n-doped layer 113.

In the embodiment of FIG. 4 low-ohmic interlayers are provided. If AlGaN layers are used, these have a low Al content, ideally below 50%, of the group-III-metal. Due to the high efficiency with respect to the stress bias, interlayers with high Al content or AlN/GaN superlattice structures are suitable, which requires an etching of the vias upto the uppermost layer 105 or 113, respectively, as shown by the vias 111 in FIG. 4

FIG. 6 shows a process flow of separating a device from a growth substrate and further processing the device with or without a carrier. By this process, carriers of high thermal conductivity may be used.

In a step shown in FIG. 6a, the substrate is removed by a mechanical process combined with etching, or only be etching. To this end, the layer 109 is glued to a carrier (not shown) in a step shown in FIG. 6b). In case this carrier is to remain connected with the device, contacts are applied before step b). The doped layer 109 is connected with the contact in this embodiment. However, a Schottky contact 107 is also possible, if applied to the layer 106, that is, if layer 109 is not present.

Optionally, the carrier for separating the growth substrate may be removed.

All lower layers up to layer 105 are removed by dry chemical etching. In case of the embodiment of FIG. 4, the process removes all layers up to layer 113. Then contacts are made, and/or the transfer to a new carrier with layer 105. A device of this kind has a low series resistance, on top of big advantages with respect to thermal conductivity, because the current distribution is very simple in a purely vertical structure like this and contacts may cover a larger area.

For fabricting the contacts in the case of vertical contacting (i.e., one contact on the back side of the carrier, one contact on the front side of the layer structure) and in the case of p-i-n diodes, the upper highly conductive layer is preferably etched down to the intrinsic layer, in a region beside the contact having an extension that at least corresponds to the layer thickness of the intrinsic layer. This way, leak currents can be avoided.

The surface is preferably passivated by an isolator suitable for resisting high voltages, such as silicon dioxide or silicon nitride.

The group-III-layers 105, 106 and 109 can be made of different group-III-nitride materials. For a p-i-n structure as in FIG. 2, AlGaN can be selected for the layers 105 and 109, layer 105 being p-doped and layer 109 being n-doped. For in the usual (0001) growth direction, a group-III-terminated surface is formed, resulting in a hole gas at the interface between layers 105 and 106, and an electron gas at the other interface. The concentration of these carrier gases is reduced in case of carrier depletion. By additional influence of the hetero barrier, the leak current is reduced. On the other hand, in the forward direction the series resistance is reduced at the hetero interface.

The structure according to the present invention can be shown to have successfully been implemented by analyzing the layers using a scanning electron microscope in combination with an EDX analysis, or by means of transmission electron microscopy and secondary ion mass spectroscopy. This way, the layers. And also the masking layers, can be detected. TEM allow identifying the type of dislocations. In case the silicon substrate is removed, the stress can be determined in a cross section by means of micro Raman measurements, or indirectly by means of highly spatially resolved luminescence measurements.

In the following, a list of reference labels used in the above specification is given, along with a short explanation of the respective structural element.

| | |
|---|---|
| 100 | substrate |
| 101 | seed and buffer layer |
| 102 | optional masking layer |
| 103 | buffer layer, either undoped, or doped and electrically |
| | conductive |
| 104 | intermediate layer or layer sequence effecting compressive |
| | stress bias during growth |
| 105 | doped layer, also referred to as the first group-III-nitride |
| | layer. In case of a Schottky diode, doping is n-type; |
| | however, in case of a p-i-n Diode doping may alternatively |
| | be p-type, if at the same time layer 109 is n-type doped. |
| 106 | undoped or low-doped n- oder p-conductive layer, also |
| | referred to as intrinsic layer (i-layer) and as second |
| | group-III-nitride layer; may however be doped intentionally, |
| | preferably at low concentration levels; |
| 107 | upper contact, forming a Schottky contact, if applied on layer |
| | 106, and forming an Ohmic contakt if applied on layer 109 |
| 108 | Ohmic back side contact |
| 109 | an upper doped layer in a p-i-n diode, complementary to |
| | layer 105 or 113, resepctively, perferably p-doped; |
| 110 | through-the-substrate/carrier back side contact structure |
| | with vias for connection to the conductive layer 105 |
| 111 | optional extension of vias in case additional intermediate |
| | layers 112 are present; in this case the extension reaches |
| | up into layer 113; |
| 112 | additional intermediate layer or layer sequence (in addition |
| | to intermediate layer 104) for increasing the compressive |
| | stress bias |
| 113 | highly n- or p-doped layer, corresponding to layer 105 |
| 114 | ohmic contact to layer 105 or 113 in case of a front side |
| | contact structure |
| 115 | application of etching process in case of a transfer of the |
| | layer structure from a growth substrate to a carrier. |

1. A group-III-nitride based layer sequence fabricated by means of an epitaxial process on a silicon substrate, the layer sequence comprising:
at least one doped first group-III-nitride layer (105) having a dopant concentration larger than 1×10¹⁸ cm⁻³;
a second group-III-nitride layer (106) having a thickness of at least 50 nm and an n-type or p-type dopant concentration of less than 5×10¹⁸ cm⁻³; and
an active region (106) made of a group-III-nitride semiconductor material;
wherein the first group-III-nitride layer comprises at least one n-type dopant selected from the group of elements formed by germanium, tin, lead, oxygen, sulphur, selenium and tellurium or a at least one p-type dopant; and wherein
the active region has a volume density of either screw-type or edge type dislocations below 5×10⁹ cm⁻³.

2. The layer sequence of claim 1, wherein the second group-III-nitride layer is low-doped with an n-type or p-type dopant concentration of less than 5×10¹⁷ cm⁻³.

3. The layer sequence of claim 2, wherein the second group-III-nitride layer has a thickness of at least 500 nm.

4. The layer sequence of claim 3, wherein the second group-III-nitride layer has a thickness of between 2 and 10 μm.

5. The layer sequence of claim 1, wherein the active region has a volume density of screw-type dislocations below 5×10⁸cm⁻³.

6. The layer sequence of claim 1, wherein the volume density of screw-type dislocations in the active region is below 1×10⁸ cm⁻³.

7. The layer sequence of claim 1, wherein the dopant concentration of the first group-III-nitride layer is an n-type dopant concentration.

8. The layer sequence of one of claim 1, wherein the dopant concentration of the first group-III-nitride layer is a p-type dopant concentration.

9. The layer sequence of claim 1, further comprising a layer of silicon nitride, silicon oxide, boron nitride or aluminum oxide or a mixture of at least two of these materials.

10. The layer sequence of claim 1, wherein the silicon substrate has a silicon-on-insulator structure.

11. The layer sequence of claim 1, wherein a volume density of edge-type dislocations in the active region is below 2×10⁹ cm⁻.

12. The layer sequence of claim 11, wherein the volume density of edge-type dislocations in the active region is below 5×10⁸ cm⁻³.

13. A semiconductor device, comprising at least one group-III-nitride based layer sequence according to claim 1.

14. The semiconductor device of claim 13, which is configured either as a Schottky diode, a p-i-n diode or as a light emitting diode.

15. The semiconductor device of claim 14, which is configured to allow a vertical flow of current through the active region.

16. The semiconductor device of claim 13, which is configured to allow a vertical flow of current through the active region.

17. The layer sequence of claim 1, wherein the second group-III-nitride layer has a thickness of at least 500 nm.
